(19) United States
(12) Patent Application Publication
(10) Pub. No.: US 2018/0295746 A1
(43) Pub. Date: Oct. 11, 2018

(54) DIVERSION STRUCTURE FOR DISPLAY CARD COOLING DEVICE

(71) Applicant: EVGA CORPORATION, New Taipei City (TW)

(72) Inventor: Tai-Sheng Han, New Taipei City (TW)

(21) Appl. No.: 15/603,397

(22) Filed: May 23, 2017

(30) Foreign Application Priority Data
Apr. 7, 2017 (TW) 106204824

(51) Int. Cl. H05K 7/20

(52) U.S. Cl. CPC H05K 7/20409; H05K 7/20172

(57) ABSTRACT

A diversion structure for a display card cooling device includes: at least one cooling fin, configured on a display card; at least one cooling module, configured on the cooling fin; at least one protective cover, configured on the display card and adapted to cover the cooling fin; and at least one first diversion portion, configured on the protective cover and positioned at the same side as the cooling module. Whereby, when the display card is in operation, extra heat will be generated, which can be absorbed by the cooling fins. In addition, the protective cover can cover the cooling fins for the protection thereof, and air is driven to flow by running the cooling modules, allowing the air inside and outside the protective cover to be circulated quickly through the first diversion portion so as to cool the display card quickly.

### (a) TECHNICAL FIELD OF THE INVENTION

The present invention relates to a diversion structure for a display card cooling device, and more particularly to a diversion structure for a display card cooling device allowing air to circulate smoothly to cool a display card quickly.

### (b) DESCRIPTION OF THE PRIOR ART

With the development of science and technology, people invent more and more tools to make life more convenient. Among these, computers are the most representative inventions; through computers, people can surf the internet to absorb knowledge, play online games, listen to music or watch movie; computers cause people to enter into information explosion era and change their life. A display card for driving a display is configured inside every computer; a cooling device configured on the display card to cool the display card because extra heat will generated in the display card to cause the temperature thereof to be increased when it is in operation and the display card will broken down without capability of operation when the temperature thereof is high. Cooling fins are the most popular cooling tools, which are used to increase the areas in contact with air. In addition fans are configured on the cooling fins to make air flow, and a protective cover is configured on the cooling tools thereby to protect them from damage. For example, Taiwan Patent NO. M387288, titled “protective cover for interface card cooling device”, uses a protective cover to cover an interface card cooling device to protect the cooling device on an interface card from damage.

However, the protective cover structure for an interface card cooling device really has the following problem and defect to be overcome while in use: although the protective cover can be used to protect the cooling device, the protective cover blocks air convection such that the air inside and outside the protective cover cannot be circulated effectively, causing the cooling effect to be lowered.

### SUMMARY OF THE INVENTION

The main object of the present invention is to provide a diversion structure for a display card cooling device, allowing the heat in a display card to be conducted to cooling fins so as to speed the cooling of the display card through the design of cooling fins.

Another object of the present invention is to provide a diversion structure for a display card cooling device, allowing air to flow quickly so as to speed the temperature drop of the cooling fins through the design of cooling modules.

To achieve the objects mentioned above, the present invention proposes a diversion structure for a display card cooling device, including: at least one cooling fin, configured on a display card; at least one cooling module, configured on the cooling fin; at least one protective cover, configured on the display card and adapted to cover the cooling fin; and at least one first diversion portion, configured on the protective cover and positioned at the same side as the cooling module. Whereby, when the display card is in operation, extra heat will be generated, and the heat in the display card can be conducted to the cooling fins, through which the surface area in contact with air is increased, allowing heat to be exchanged with air quickly. In addition, the protective cover can cover the cooling fins for the protection thereof, and air is driven to flow by running the cooling modules, allowing the air inside and outside the protective cover to be circulated quickly through the first diversion portions so as to cool the display card quickly.

With the technologies mentioned the present invention can overcome the defects of conventional protective cover structure for an interface card cooling device mentioned above and increase display card cooling efficiency.

### BRIEF DESCRIPTION OF THE DRAWINGS

FIG. 1 is a perspective view of a preferred embodiment of the present invention;

FIG. 2 is an exploded view of the embodiment of the present invention; and

FIG. 3 is a perspective view of the embodiment of the present invention in implementation.

### DETAILED DESCRIPTION OF THE PREFERRED EMBODIMENTS

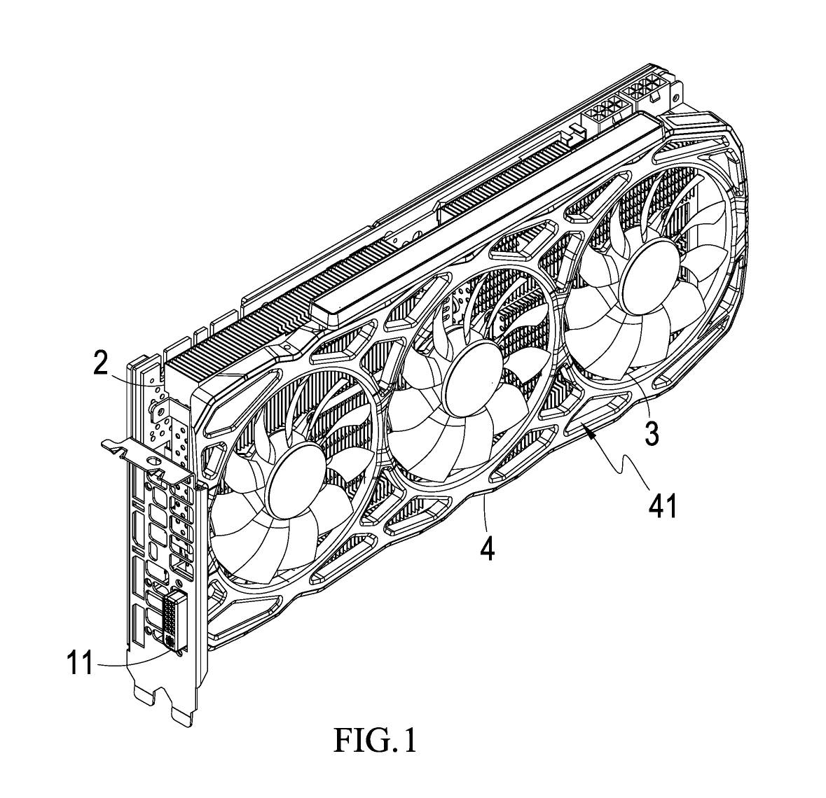

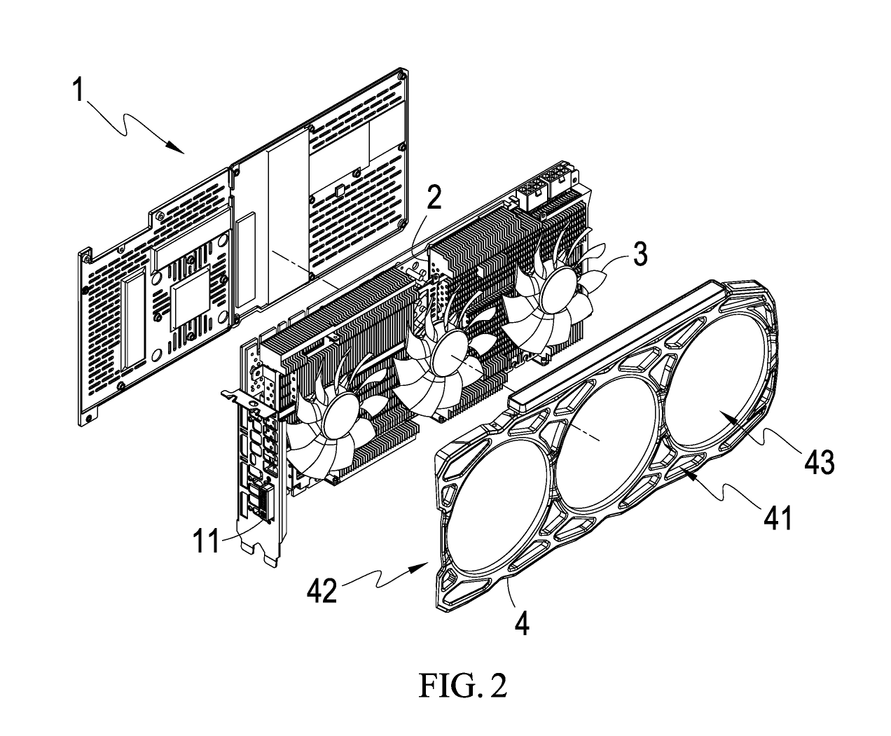

Referring to FIGS. 1 and 2, a diversion portion structure for a display card cooling device of the present invention includes: at least one cooling fin 2, configured on a display card 1, at least one transmission conductor 11 in electric connection with the display card 1 being configured on one side of the display card 1; at least one cooling module 3, configured on the cooling fin 2, and being a fan; at least one protective cover 4, configured on the display card 1 and adapted to cover the cooling fin 2, at least one first diversion portion 41 configured on the protective cover 4 and positioned at the same side as the cooling module 3, and at least one second diversion portion 42 configured on one side of the cooling fin 2 between the protective cover 4 and display card 1; and at least one third diversion portion 43, configured on the protective cover 4 and positioned correspondingly to the cooling module 3, and adapted to accommodate the cooling module 3, where the first, second and third diversion portions 41, 42 and 43 respectively are a through hole.

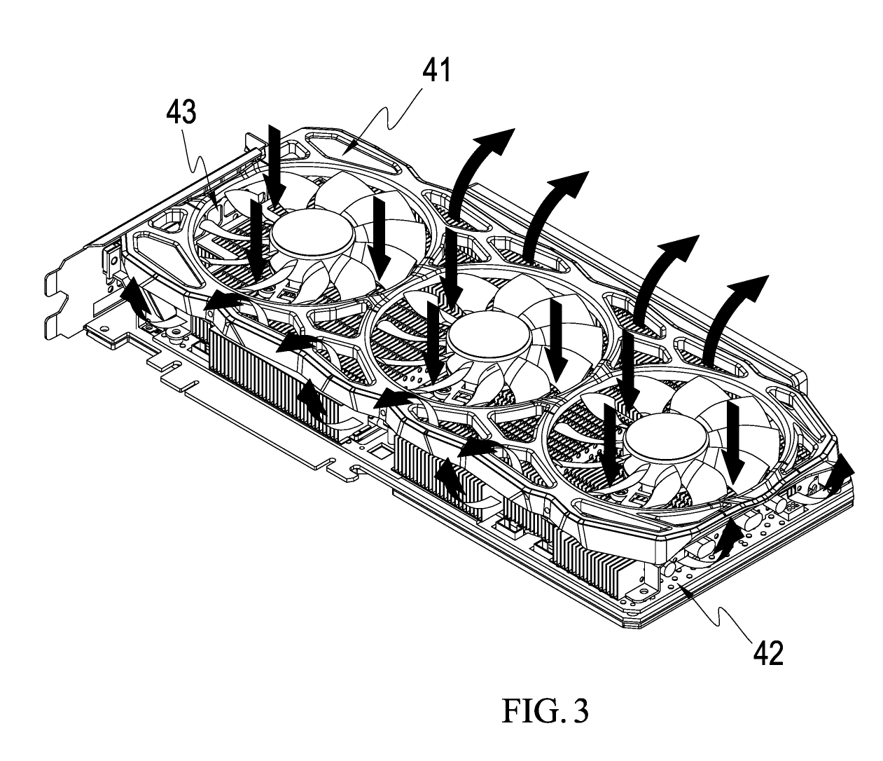

Referring to FIGS. 1, 2 and 3, extra heat will be generated when the display card 1 is in operation; if the temperature of the display card 1 is not lowered but increased continuously, the display card 1 will be broken down due to overheat, leading the display card 1 to be incapable of normal use. At this time, the heat in the display card 1 is conducted to the cooling fin 2 by contacting the cooling fin 2 with the display card 1, where the cooling fin 2 is made of quick heat conduction metal and has a large area, capable of cooling the display card 1 quickly. To protect the cooling fins 2 and display card 1, the protective cover 4 is configured to cover the cooling fins 2, and to accommodate the cooling module 3, the second diversion portions 42 are configured on the protective cover 4. Furthermore, air is allowed to flow quickly through the running of the cooling module 3. In addition, the heated air generated from the heat exchange with the cooling fins 2 and cool air outside the protective cover 4 can be circulated smoothly through the through holes such as the first, second and third diversion portions 41, 42 and 43, thereby allowing the air to flow through the cooling fins 2 from all directions so as to cooling the display card 1 quickly. In addition, the transmission conduction portion 11 in electric connection with the display card 1 is a terminal of the display card 1 for the electric connection of a display with the display card 1, allowing the display card 1 to drive the display for a user's convenient operation.

Thereupon, the diversion structure for a display card cooling device has the following advantages over the prior arts:

1. allowing the heat to be conducted to the cooling fins 2 so as to speed the cooling of the display card 1 through the design of the cooling fins 2;

2. allowing air to flow quickly to speed the temperature drop of the cooling fins 2 through the design of the cooling modules 3;

3. capable of protecting the cooling fins 2 and display card 1 from damage through the design of the protective cover 4; and

4. allowing air to be circulated smoothly through the designs of the first, second and third diversion portions 41, 42 and 43.

1. A diversion structure for a display card cooling device, comprising:
at least one cooling fin, which is positioned on and in contact with a display card to receive heat from the display card such that the heat is dissipated to air that is subjected to heat exchange with the cooling fin so as to produce heated air;
at least one cooling module, configured on said cooling fin;
at least one protective cover, configured on said display card and adapted to cover said cooling fin; and
at least one first diversion portion, configured on said protective cover and positioned at the same side as said cooling module;
wherein the first diversion portion allows the heated air produced by the heat dissipated from the cooling fin and cool air outside the protective cover to circulate through the first diversion portion for cooling the display card quickly.

2. The structure according to claim 1, wherein at least one second diversion portion is configured between said protective cover and display card, and positioned on one side of said cooling fin.

3. The structure according to claim 2, wherein at least one third diversion portion corresponding to said cooling module is configured on said protective cover for the accommodation of said cooling module structure according to claim 2, wherein at least one third diversion portion corresponding to said cooling module is configured on said protective cover for the accommodation of said cooling module.

4. The structure according to claim 3, wherein said first diversion portion, second diversion portion and third diversion portion respectively are a through hole.

5. The structure according to claim 1, wherein at least one transmission conduction portion in electric connection with said display card is configured on one side of said display card.

6. The structure according to claim 1, wherein said cooling module is a fan.
